(19) United States
(12) Patent Application Publication
(10) Pub. No.: US 2012/0224717 A1
(43) Pub. Date: Sep. 6, 2012

(54) AUDIO CABLE CAPABLE OF INCREASING GAIN AND FILTERING NOISE

(76) Inventor: Ko-Chung Teng, Beijing (CN)

(21) Appl. No.: 13/502,032

(22) PCT Filed: Mar. 10, 2010
(86) PCT No.: PCT/CN2010/000294

§ 371 Date: Apr. 13, 2012

(30) Foreign Application Priority Data
Nov. 9, 2009 (CN) 200920278735.5

(51) Int. Cl. H04B 15/00; H03F 99/00; H03G 3/00

(52) U.S. Cl. 381/94.1

(57) ABSTRACT

An audio cable capable of increasing gain and filtering noise includes a signal amplifier arranged between an input end and an output end of the audio cable. The signal amplifier includes at least a primary coil and a secondary coil. The number of turns of the secondary coil is greater than that of the primary coil. A mutual inductance between the primary coil and the secondary coil can transform the level of voltage, current and impedance of the signal amplifier to generate an output gain greater than 1, so as to amplify the audio signal. Moreover, the primary and secondary coils have a characteristic of blocking fast current variation; thereby the higher the gain magnification, the more stable is the sound quality and the smaller the noise becomes.

### BACKGROUND OF THE INVENTION

1. Field of the Invention

The present invention relates to an audio cable adapted for use in amplifiers or earphones.

2. The Prior Arts

An audio cable is generally connected between a content player and an audio output device. An adjusting element provided on the content player or the audio output device can be used to adjust the volume of the audio output. For example, an audio cable is connected between a DVD player and a signal amplifier, and a rotary knob on the amplifier can be used to adjust the sound volume. In another example, an earphone is connected with a handheld content player, and a button on the handheld content player can be pressed to adjust the sound volume.

However, some problems may occur during use, for example excessively small volume, and the occurrence of noise during listening, or tuning volume or bass. Moreover, the occurrence of noise may increase when the volume is increased for clearer listening.

### SUMMARY OF THE INVENTION

An objective of the present invention is to provide an audio cable that can solve the problems of excessively small sound volume and noise occurrence.

An audio cable in accordance with the present invention comprises a signal amplifier arranged between an input end and an output end of the audio cable. The signal amplifier comprises at least a primary coil and a secondary coil. The number of turns of the secondary coil is greater than that of the primary coil. A mutual inductance between the primary coil and the secondary coil can transform the level of voltage, current and impedance to generate an output gain greater than 1, so as to amplify an audio signal. In order to generate a gain greater than 1, the coils can be configured as follows:

(1) First configuration of the coils: The primary coil and the secondary coil have a fixed number of coil turns, and the number of turns of the secondary coil is greater than that of the primary coil;

(2) Second configuration of the coils: Two or more sets of the primary coils and the secondary coils are used. Each set of coils respectively is connected to a different output end; thereby having multiple output ends in this configuration; and

(3) Third configuration of the coils: The primary coil and the secondary coil can be adjusted in the number of coil turns, and two rotary knobs or buttons are arranged on a surface of the signal amplifier and connected with the primary coil and the secondary coil to adjust the number of turns of the primary coil and the secondary coil, respectively.

All of the configurations of the coils described above can generate a magnified voltage, current or power, thereby amplifying an audio signal. Furthermore, the coils have a characteristic of blocking fast current variation; thereby the higher the gain magnification, the more stable is the sound quality and the smaller the noise becomes.

### BRIEF DESCRIPTION OF THE DRAWINGS

The present invention will be apparent to those skilled in the art by reading the following detailed description of preferred embodiments thereof, with reference to the attached drawings, in which:

FIG. 1 is a schematic view showing an audio cable according to an embodiment of the present invention;

FIG. 2 is a circuit diagram of a signal amplifier according to a first embodiment of the present invention;

FIG. 3 is a circuit diagram of a signal amplifier according to a second embodiment of the present invention;

FIG. 4 is a circuit diagram of a signal amplifier according to a third embodiment of the present invention; and

FIG. 5 is a schematic view showing a signal amplifier according to another embodiment of the present invention.

### DETAILED DESCRIPTION OF THE PREFERRED EMBODIMENTS

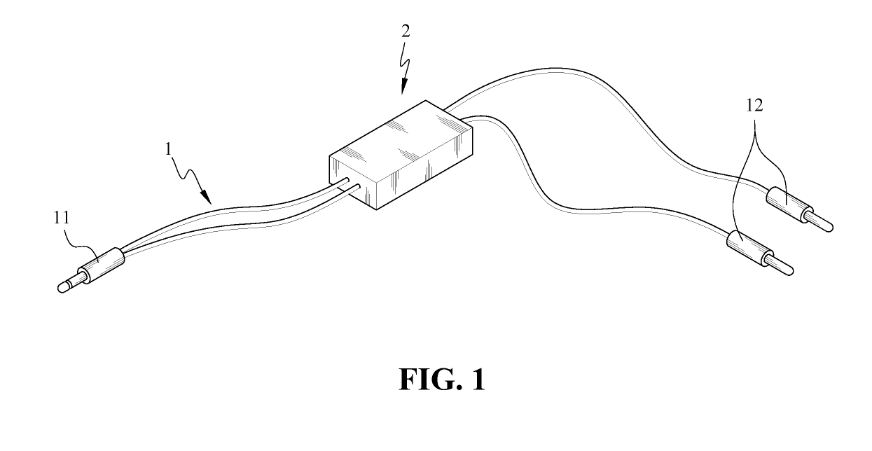

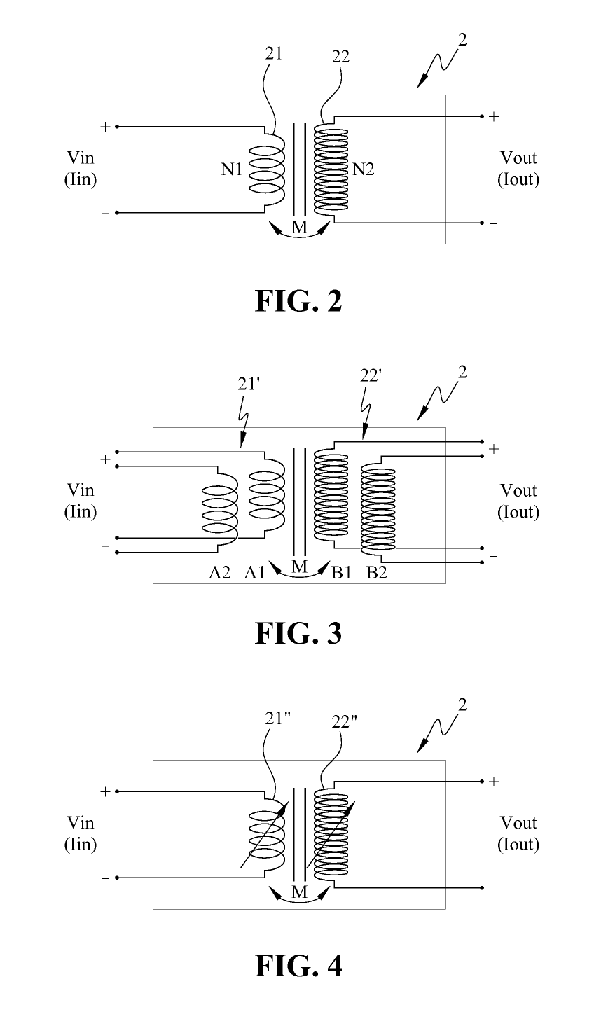

FIG. 1 is a schematic view showing an audio cable capable of increasing gain and filtering noise according to an embodiment of the present invention. An audio cable 1 according to the present invention comprises a signal amplifier 2 that can amplify audio signals and filter noise. The audio cable 1 can be used as a connection between a content player and an audio output device. The content player can be a DVD player, a handheld audio player, and the like that can play content. The audio output device can be a speaker amplifier, an earphone, and the like. The audio cable 1 is connected between the content player and the audio output device. The audio cable 1 has an input end 11 and an output end 12 that can transmit and receive an audio signal. The signal amplifier 2 is arranged between the input end 11 and the output end 12 of the audio cable 1. FIG. 2 shows a circuit diagram of a signal amplifier 2 according to a first embodiment of the present invention. The signal amplifier 2 mainly includes a primary coil 21 and a secondary coil 22. Because the electric current is influenced by the number of coil turns, the number of turns of the secondary coil 22 is greater than that of the primary coil 21 for increasing the output gain. When a current flows through the primary coil 21, a mutual inductance (represented as symbol “M”) between the primary coil 21 and the secondary coil 22 can transform the level of voltage, current and impedance of the signal amplifier to generate an output gain greater than 1. The gain may be a voltage gain (Vₒᵤₜ/Vᵢₙ=e, and e≧1), a current gain (Iₒᵤₜ/Iᵢₙ=e′, and e′≧1), or a power gain, so as to amplify the audio signal. The coils have a characteristic of blocking fast current variations; thereby the higher the gain magnification, the more stable is the sound quality and the smaller the noise becomes.

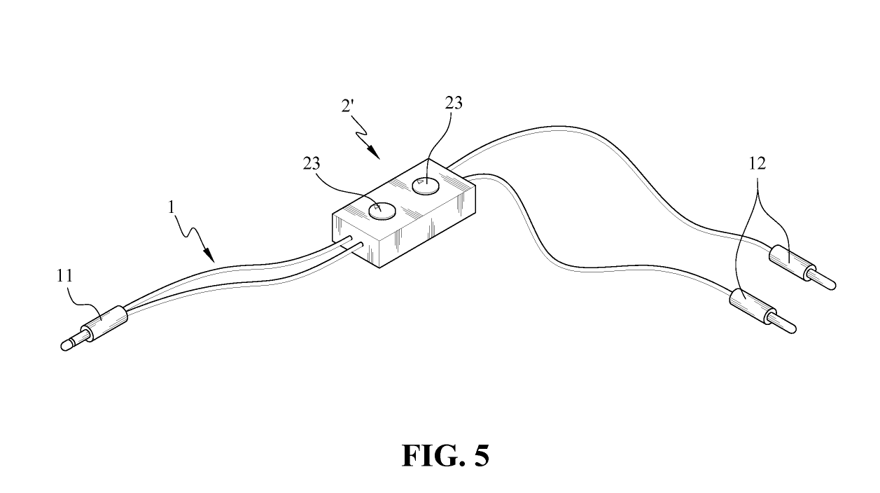

The coils can be configured as follows to generate a gain greater than 1. FIG. 2 is a schematic view showing a first configuration of the primary coil 21 and the secondary coil 22. The primary coil 21 and the secondary coil 22 have a fixed number of coil turns. Moreover, the number of turns N2 of the secondary coil 22 is greater than the number of turns N1 of the primary coil 21. For example, if N1 is set to 10 and N2 is set to 50, because the induction voltage is proportional to the turn ratio of the coils, a voltage gain magnification of 5 will be produced. FIG. 3 is a schematic view showing a second configuration, which has two sets of coils each including a primary coil 21′ and a secondary coil 22′. Each of the coils has a fixed number of coil turns. Moreover, the two sets of coils have identical coil turn ratio. For example, suppose that the number of turns A1 of the first primary coil is set to 50, and the number of turns A2 of the second primary coil is set to 35, the number of turns B1 of the first secondary coil and the number of turns B2 of the second secondary coil are equal to 100 and 70, respectively. Each secondary coil has a double of the number of turns of the corresponding primary coil. Each set of coils is respectively connected with a different output end, so that the signal amplifier can have multiple output ends (FIG. 1 shows two output ends 12). FIG. 4 is a schematic view showing a third configuration of a primary coil 21″ and a secondary coil 22″, which can be adjusted in the number of coil turns. In this configuration, two rotary knobs 23 (see FIG. 5) or buttons are arranged on a surface of the signal amplifier 2′ and connected with the primary coil 21″ and the secondary coil 22″, respectively, so that a user can adjust the number of turns of the coils. Alternatively, it is also possible that one of the primary and secondary coils has a fixed number of turns, and the number of turns of the other coil can be adjusted.

All of the configurations of the coils described above can generate a magnified voltage, current or power, thereby amplifying the audio signal. Furthermore, the coils have a characteristic of blocking fast current variations; thereby the higher the gain magnification, the more stable is the sound quality and the smaller the noise becomes.

The foregoing description is intended to only provide illustrative ways of implementing the present invention, and should not be construed as limitations to the scope of the present invention. While the foregoing is directed to embodiments of the present invention, other and further embodiments of the invention may thus be devised without departing from the basic scope thereof, and the scope thereof is determined by the claims that follow.

What is claimed is:

1. An audio cable capable of increasing gain and filtering noise, the audio cable comprising a signal amplifier arranged between an input end and an output end of the audio cable, the signal amplifier comprising at least a primary coil and a secondary coil, wherein the number of turns of the secondary coil is greater than that of the primary coil, a mutual inductance between the primary coil and the secondary coil transforms the level of voltage, current and impedance of the signal amplifier to generate an output gain greater than 1, the coils have a characteristic of blocking fast current variation; thereby the higher the gain magnification, the more stable is the sound quality and the smaller the noise becomes.

2. The audio cable as claimed in claim 1, wherein the gain is a voltage gain, a current gain, or a power gain.

3. The audio cable as claimed in claim 1, wherein the primary coil and the secondary coil each have a fixed number of coil turns.

4. The audio cable as claimed in claim 1, wherein the primary coil and the secondary coil enable to be adjusted in the number of coil turns, and two rotary knobs or buttons are arranged on a surface of the signal amplifier adapted for adjusting the number of turns of the primary coil and the secondary coil, respectively.

5. The audio cable as claimed in claim 1, wherein the primary coil has a fixed number of coil turns, the secondary coil enables to be adjusted in the number of coil turns, and a rotary knob or button is arranged on a surface of the signal amplifier adapted for adjusting the number of turns of the secondary coil.
